(19) United States
(12) Patent Application Publication
(10) Pub. No.: US 2026/0206563 A1
(43) Pub. Date: Jul. 16, 2026

(54) THROUGH SILICON VIA (TSV) LANDING ON NARROW METAL

(71) Applicant: QUALCOMM Incorporated, San Diego, CA (US)

(72) Inventors: Junjing BAO, San Diego, CA (US); Abhishek JAIN, San Diego, CA (US); Hyun LEE, San Diego, CA (US); Jihong CHOI, San Diego, CA (US)

(21) Appl. No.: 19/298,039

(22) Filed: Aug. 12, 2025

Related U.S. Application Data
(60) Provisional application No. 63/744,135, filed on Jan. 10, 2025.

(51) Int. Cl. H10W 20/20; H10W 20/00; H10W 20/42

(52) U.S. Cl. CPC H10W 20/20; H10W 20/023; H10W 20/057; H10W 20/082; H10W 20/42

(57) ABSTRACT

An integrated circuit (IC) is described. The IC includes a substrate as well as an interlayer dielectric (ILD) layer adjacent to the substrate. The IC also includes a front-end-of-line (FEOL) layer between the substrate and the ILD layer. The IC further includes back-end-of-line (BEOL) metal interconnects in the ILD layer. The IC also includes a through silicon via (TSV), partially extending through the ILD layer, landing on a first metal layer interconnect of the BEOL metal interconnects. A critical dimension (CD) of the TSV is greater than or equal to a width of the first metal layer interconnect.

### CROSS-REFERENCE TO RELATED APPLICATION

The present application claims the benefit of U.S. Provisional Patent Application No. 63/744,135, filed January 10, 2025, and titled “THROUGH SILICON VIA (TSV) LANDING ON NARROW METAL,” the disclosure of which is expressly incorporated by reference in its entirety.

### BACKGROUND

### Field

Aspects of the present disclosure relate to semiconductor devices and, more particularly, to a through silicon via (TSV) landing on a narrow metal.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

For example, these electrical connects include through silicon vias (TSVs) that land on a wide metal to ensure a complete connection between the TSV and the wide metal because a critical dimension (CD) of the TSV is less than a width of the wide metal. Unfortunately, lower metal layer (e.g., metal one (M1)) interconnects have a maximum width that is less than the CD of the TSV. As a result, implementations are forced to land the TSV on upper metal interconnects. This forced landing of the TSV on upper metal interconnects results in a keep out zone (KOZ) that wastes valuable area at a lower metal layer (e.g., M1). Additionally, the forced landing of the TSV on upper metal interconnects involves an etch and metal filling process that leads to a high yield risk during formation of a high aspect ratio (AR) TSV.

### SUMMARY

An integrated circuit (IC) is described. The IC includes a substrate as well as an interlayer dielectric (ILD) layer adjacent to the substrate. The IC also includes a front-end-of-line (FEOL) layer between the substrate and the ILD layer. The IC further includes back-end-of-line (BEOL) metal interconnects in the ILD layer. The IC also includes a through silicon via (TSV), partially extending through the ILD layer, landing on a first metal layer interconnect of the BEOL metal interconnects. A critical dimension (CD) of the TSV is greater than a width of the first metal layer interconnect.

A method for forming a via landing on a narrow metal is described. The method includes etching a via opening through a substrate and at least partially through an interlayer dielectric (ILD) layer. The method also includes stopping the etching of the via opening on an etch stop layer to expose back-end-of-line (BEOL) metal interconnects. The method further includes plating the via opening to form a through silicon via (TSV), partially extending through the ILD layer, landing on a first metal layer interconnect of the BEOL metal interconnects. A critical dimension (CD) of the via is greater than a width of the first metal layer interconnect.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), including a through silicon via (TSV) landing on a narrow metal, in accordance with various aspects of the present disclosure.

FIG. 2 is a block diagram illustrating a cross-section of an integrated circuit (IC) device including an interconnect stack.

FIGS. 3A and 3B show cross-sectional and top-down views illustrating an integrated circuit (IC), having backside through silicon vias (BTSVs) landing on a narrow metal, according to various aspects of the present disclosure.

FIGS. 4A-4D are block diagrams illustrating formation of the integrated circuit (IC) of FIGS. 3A and 3B, according to various aspects of the present disclosure.

FIG. 5 is a process flow diagram illustrating a method for forming a through silicon via (TSV) landing on a narrow metal, according to various aspects of the present disclosure.

FIG. 6 is a block diagram showing an exemplary wireless communications system in which a configuration of the disclosure may be advantageously employed.

FIG. 7 is a block diagram illustrating a design workstation used for circuit, layout, and logic design of a through silicon via (TSV) landing on a narrow metal, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Electrical connections exist at each level of a system hierarchy. This system hierarchy includes interconnection of active devices at a lowest system level all the way up to system level interconnection at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes. In integrated circuit fabrication, active devices (e.g., transistors) are built first (at the front end of the manufacturing line or front-end-of-line (FEOL), while the interconnects, or the wiring, are built thereafter, at the back end of the manufacturing line (BEOL). In some implementations, there are middle-of-line (MOL) processes between FEOL and BEOL processes.

In general, active devices can include components formed on a front-end-of-line (FEOL) layer and/or the substrate. The active devices can include transistors in a logic circuit, a memory cell (e.g., a DRAM cell), etc., whereas interconnections include back-end-of-line (BEOL) interconnect layers, which may refer to the conductive interconnect layers (e.g., a first BEOL interconnect layer or metal one (M1), metal two (M2), metal three (M3), metal four (M4), etc.) for electrically coupling to active devices of an integrated circuit. The various BEOL interconnect layers are formed at corresponding BEOL interconnect levels, in which lower metal layer BEOL interconnect levels use thinner metal layers relative to upper BEOL interconnect levels. The BEOL interconnect layers may electrically couple to middle-of-line (MOL) interconnect layers, for example, to connect an M1 metal layer to an oxide diffusion (OD) layer of an integrated circuit. The MOL interconnect layer may include a zero-metal layer (M0) interconnect, and a zero via (V0) for connecting an M1 metal layer interconnect to an active device layer, such as an FEOL layer of an integrated circuit.

These electrical connections include through silicon vias (TSVs) that may be used for wafer bonding. In practice, high aspect ratio (AR) through silicon vias (TSVs) (e.g., ~10:1) are used to perform the wafer bonding. For example, the wafer bonding may include logic-to-dynamic random-access memory (DRAM) bonding, DRAM-to-DRAM bonding, and the like. Currently a TSV lands on a wide metal (e.g., M2 interconnects) to ensure a complete connection between the TSV and the wide metal because a critical dimension (CD) of the TSV is less than a width of the wide metal. Unfortunately, lower metal layer (e.g., M1) interconnects have a maximum width that is less than the CD of the TSV. As a result, implementations are forced to land the TSV on upper metal interconnects. This forced landing of the TSV on upper metal interconnects results in a keep out zone (KOZ) that wastes valuable area at a lower metal layer (e.g., M1). Additionally, the forced landing of the TSV on upper metal interconnects involves an etch and metal filling process that leads to a high yield risk during formation of a high aspect ratio (AR) TSV.

Various aspects of the present disclosure are directed to formation of a TSV landing on a narrow metal, in which a critical dimension (CD) of the TSV is greater than a width of the narrow metal. A process flow for fabrication of an a TSV landing on a narrow metal may include front-end-of-line (FEOL) processes, middle-of-line (MOL) processes, and back-end-of-line (BEOL) processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced.

According to various aspects of the present disclosure, a TSV lands on a narrow metal, in which a CD of the TSV is greater than a width of the narrow metal. In some implementations, the via is formed in an integrated circuit (IC), including a substrate and an FEOL layer. Additionally, the IC includes BEOL metal layers on the FEOL layer and an interlayer dielectric (ILD) layer. In various aspects of the present disclosure, the TSV lands on the first metal layer of the BEOL metal layers, partially through and the ILD layer. In some implementations, an etch stop layer is on a backside of the first metal layer of the BEOL metal layers. The etch stop layer may be utilized to prevent TSV etch punch-through.

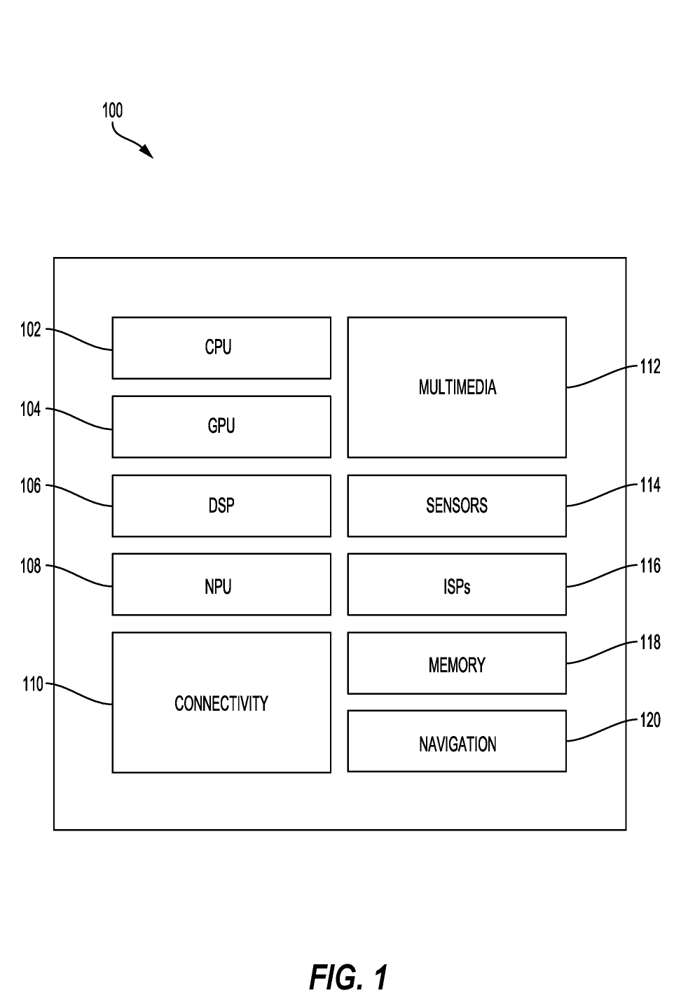

0023] FIG. 1 illustrates an example implementation of a host system-on-chip (SoC) 100, which includes a through silicon via (TSV) landing on a narrow metal, in accordance with various aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

0024] In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set

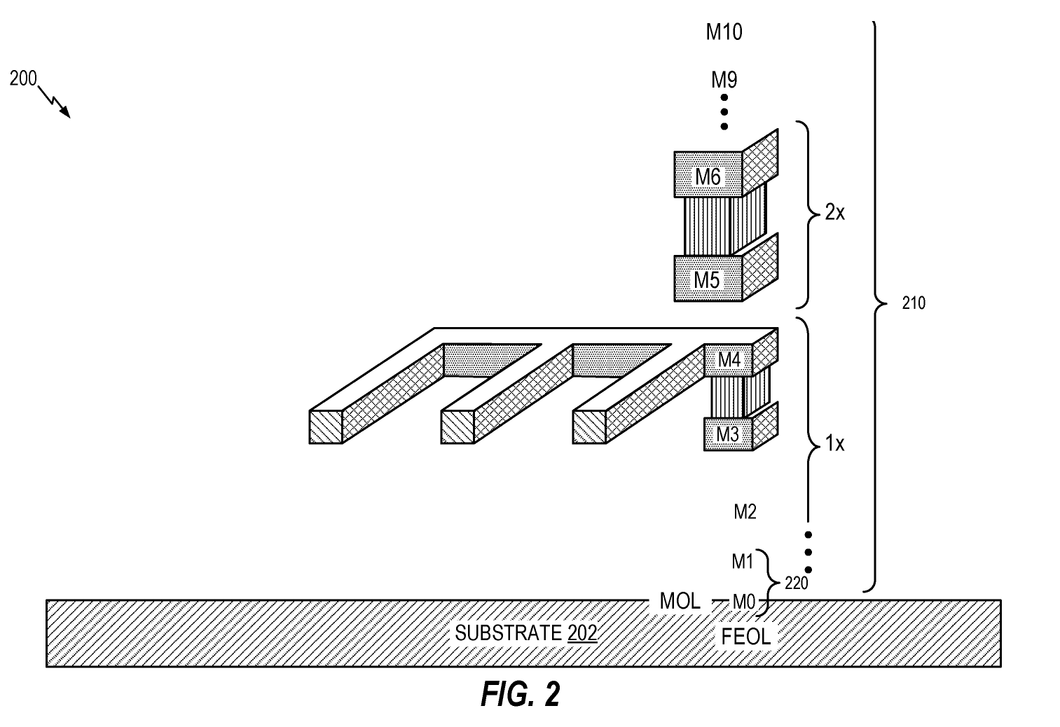

FIG. 2 is a block diagram illustrating a cross-section of an integrated circuit (IC) device 200 including an interconnect stack 210. The interconnect stack 210 of the IC device 200 includes multiple back-end-of-line (BEOL) conductive interconnect layers (M1, …, M9, M10) on a semiconductor substrate 202 (e.g., a diced silicon wafer). The semiconductor substrate 202 may be fabricated to include an active device layer (e.g., a front-end-of-line (FEOL) layer) using complementary metal oxide semiconductor (CMOS) technology. Additionally, the interconnect stack 210 includes a middle-of-line (MOL) layer to connect the FEOL layer to a first metal layer (M1) interconnect through a metal zero (M0) layer and a zero via (V0). The various BEOL interconnect layers are formed at corresponding BEOL interconnect levels, in which lower metal layer BEOL interconnect levels (e.g., M1) use thinner metal layers relative to upper (e.g., M9) BEOL interconnect levels, and the MOL layer (e.g., M0) uses thinner metal layers relative to the M1 metal layer, including local contacts (C0). In this example, an interconnect structure 220 (e.g., a through silicon via (TSV) landing on a narrow metal) is formed to land on a backside of the M1 metal layer.

Electrical connections exist at each level of a system hierarchy. These electrical connections include through silicon vias (TSVs) that may be used for wafer bonding. Currently a TSV lands on wide metal to ensure a complete connection between the TSV and the wide metal because a critical dimension (CD) of the TSV is less than a width of the wide metal. Unfortunately, lower metal layer (e.g., M1) interconnects have a maximum width that is less than the CD of the TSV. As a result, implementations are forced to land the TSV on upper metal interconnects. This forced landing of the TSV on upper metal interconnects results in a keep out zone (KOZ) that wastes valuable area at a lower metal layer (e.g., M1). Additionally, the forced landing of the TSV on upper metal interconnects involves an etch and metal filling process that leads to a high yield risk during formation of a high aspect ratio (AR) TSV.

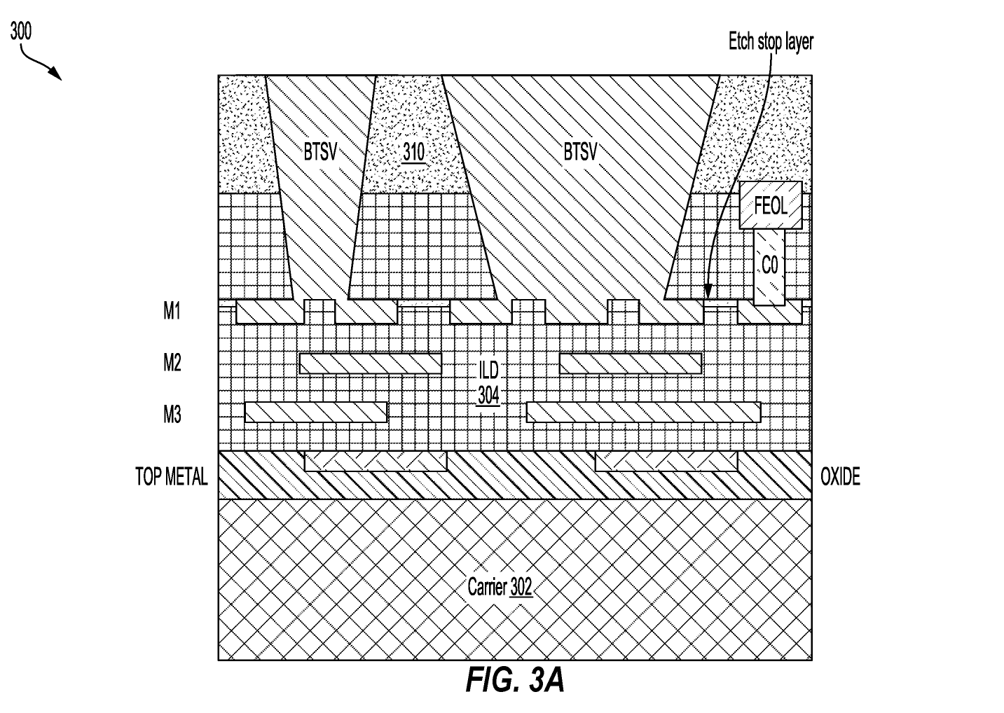

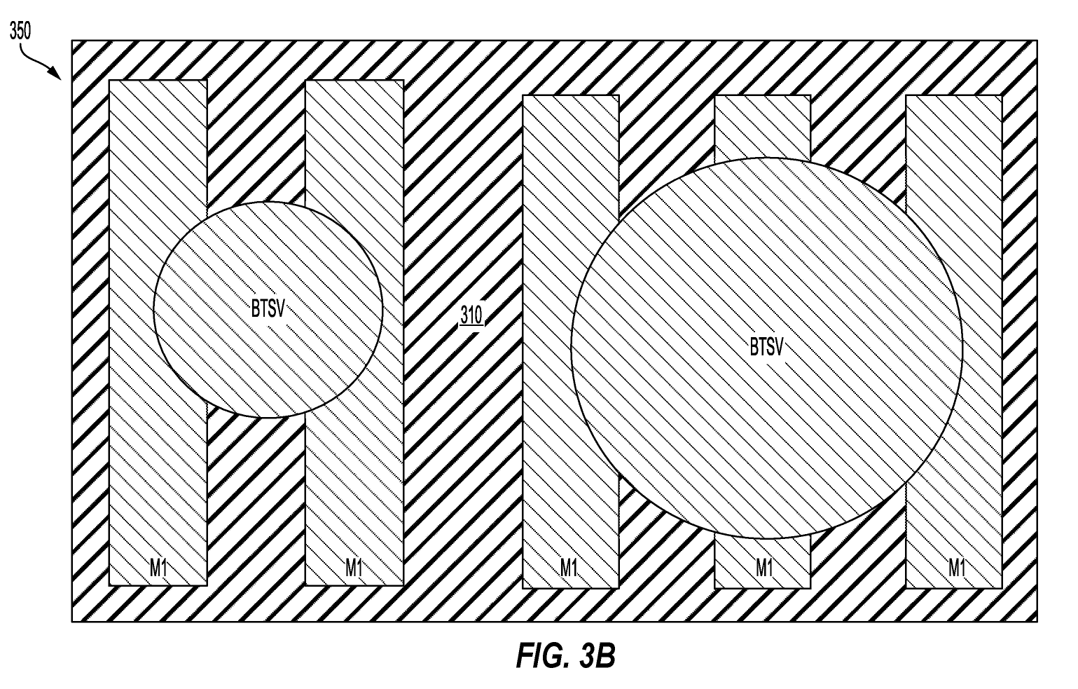

In conventional implementations, the M1 metal interconnects are intentionally over-etched to ensure full contact with underlying C0 contacts. Unfortunately, the wider M1 metal interconnects incur dishing following a chemical mechanical polishing (CMP) process. Excessive CMP and dishing of the M1 metal interconnections risks damaging the underlying C0 contacts (e.g., a tungsten (W) plug underneath the M1 metal interconnects). In practice, a maximum width of the M1 metal interconnects is substantially (e.g., >50%) smaller than a CD of backside through silicon vias (BTSVs) (e.g., BTSV CD width is 2.5μm, with a pitch 5μm, and M1 maximum width is 1μm). As a result, conventional BTSVs are chosen to land on M2 metal interconnects or above. Consequently, a layout area of the M1 metal interconnects is wasted due to TSV KOZ rules. Various aspects of the present disclosure are directed to formation of a TSV landing on a narrow metal, in which the CD of the TSV is greater than a width of the narrow metal, for example, as shown in FIGS. 3A and 3B.

FIGS. 3A and 3B show cross-sectional and top-down views illustrating an integrated circuit (IC) 300, having backside through silicon vias (BTSVs) landing on a narrow metal, according to various aspects of the present disclosure. As shown in FIG. 3A, the IC 300 includes an interlayer dielectric (ILD) layer 304 of a first dielectric material (e.g., a low-K oxide material) supported by an oxide layer including a top back-end-of-line (BEOL) metal layer. Additionally, the IC 300 includes BEOL metal interconnects (e.g., M1, M2, M3, …) in the ILD layer 304. In this example, a middle-of-line (MOL) layer is shown, including a local contact (C0), coupled to a backside of an M1 metal interconnect. According to various aspects of the present disclosure, an etch stop layer (ESL) is formed on the backside of the M1 metal interconnects to enable formation of BTSVs extending through a backside of a substrate 310 and landing on the backside of the M1 metal interconnects. A carrier wafer is bonded to the oxide of the top BEOL metal interconnect of the IC 300.

FIG. 3B shows a top-down view 350 further illustrating the BTSVs of the IC 300 of FIG. 3A, according to aspects of the present disclosure. In FIG. 3B, formation of the BTSVs is shown landing on the M1 metal interconnects, in which a critical dimension (CD) of the BTSVs is greater than a width of the narrow M1 metal interconnects. In some implementations, the BTSVs are formed in the IC 300, extending through a backside of the substrate 310 (e.g., silicon), having front-end-of-line (FEOL) layers; and partially through the ILD layer 304.

As shown in FIG. 3A, the BTSVs land on both the M1 metal interconnects and an etch stop layer (ESL) on the ILD layer 304. In some alternative implementations, the ESL on the backside of the M1 metal interconnects is completely removed. The ESL may be utilized to prevent BTSV etch punch-through. For example, ILD to etch stop layer etch ratio (e.g., >5) results in a predetermined etch selectivity and enables the TSV etch to stopping on ESL. In this example, the ESL is composed of silicon carbon-nitride (SiCN) and the ILD layer is composed of silicon carbon oxygen hydrogen (SiCOH). Although portions of the ESL remain after formation of TSV openings for forming the BTSVs, in some implementations, the noted portions of the ESL are removed during formation of the openings for the BTSVs.

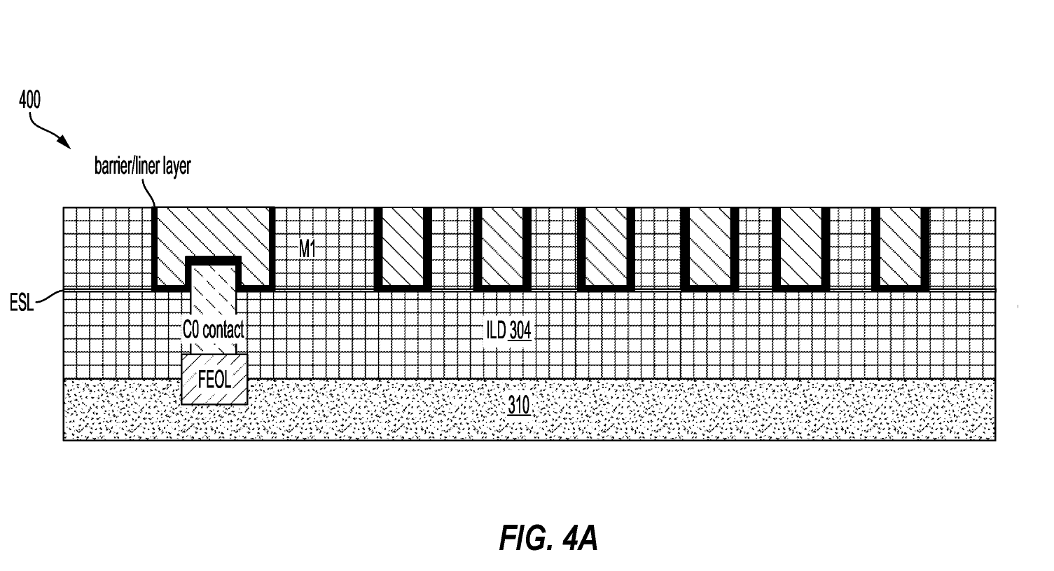

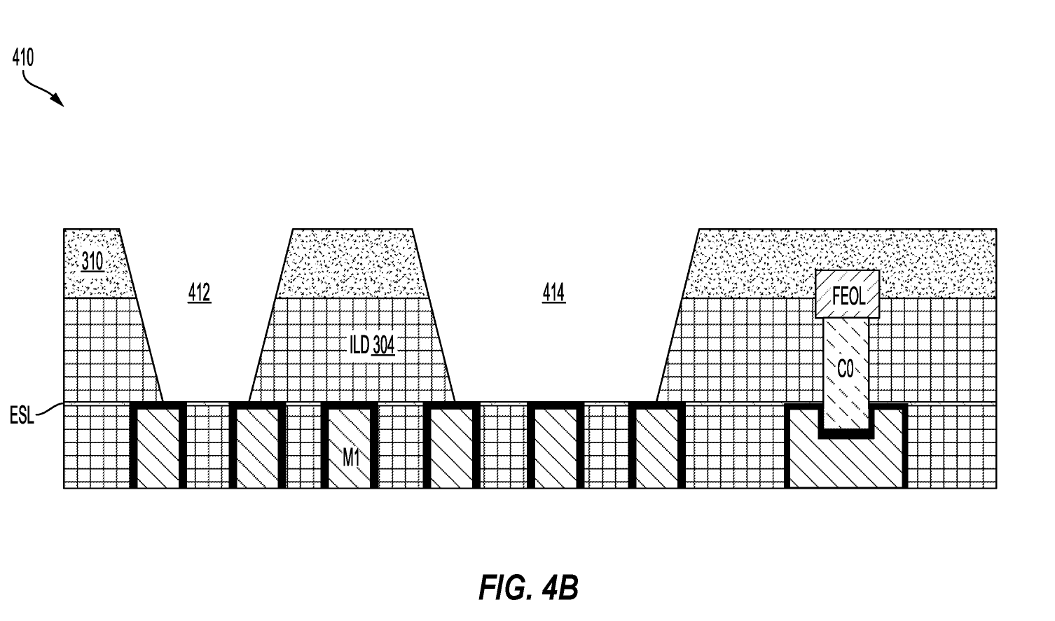

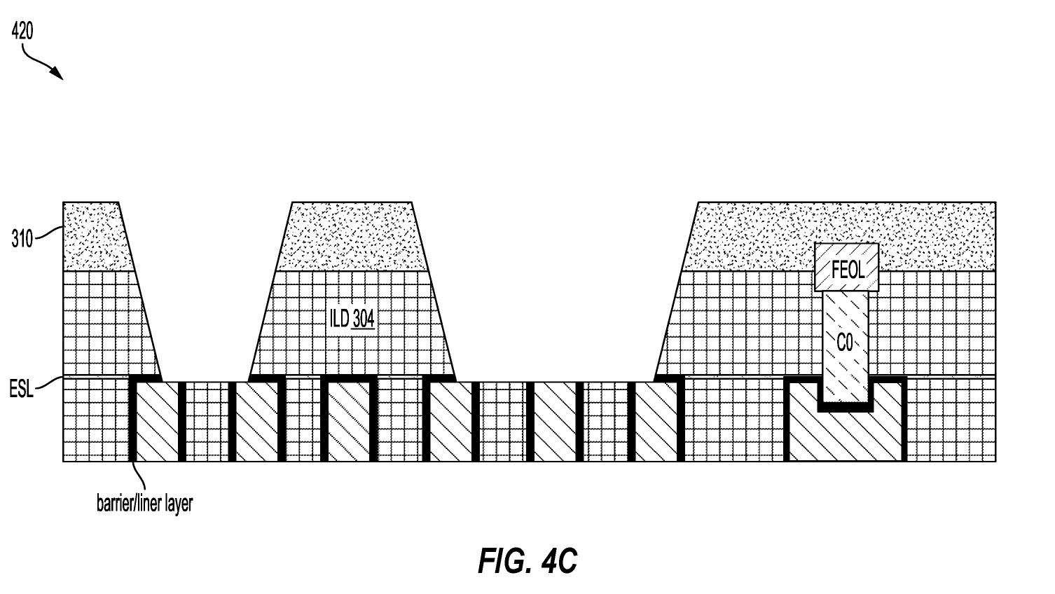

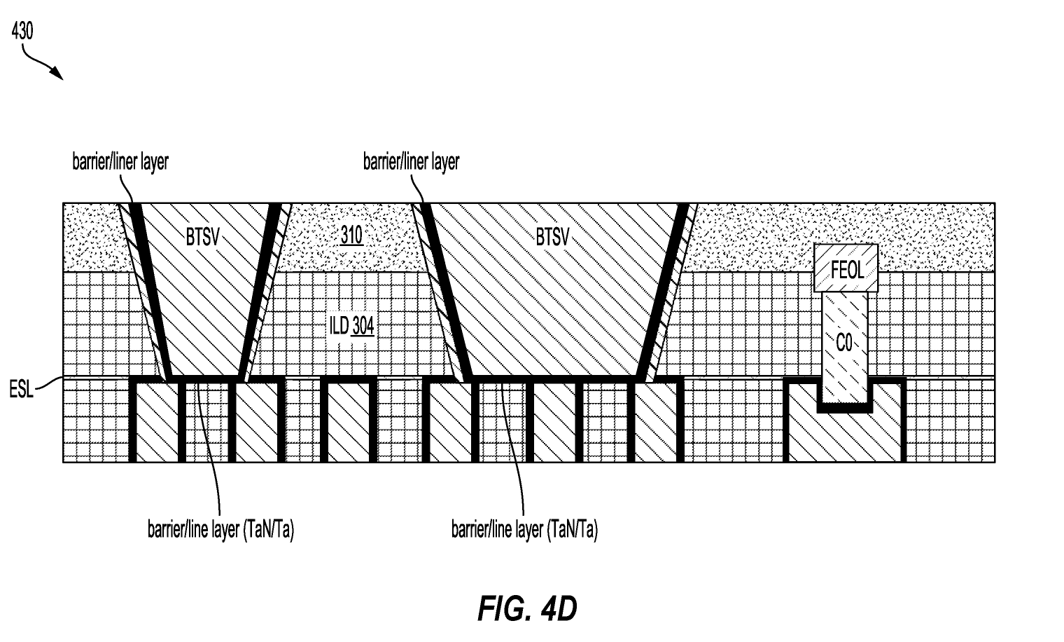

FIGS. 4A-4D are block diagrams illustrating formation of the integrated circuit (IC) 300 of FIGS. 3A and 3B, according to various aspects of the present disclosure.

As shown in FIG. 4A, an IC device fabrication process begins at step 400, in which an etch stop layer (ESL) is formed on a backside of a layer of M1 metal interconnects during frontside processing. In this example, the layer of M1 metal interconnects is formed in the ILD layer 304. Additionally, a middle-of-line (MOL) layer is shown, including a local contact C0, coupled to a backside of an M1 metal interconnect. In this implementation, the ESL (e.g., silicon nitride (SiN), titanium nitride (TiN), tantalum nitride (TaN), hafnium oxide (HfO2), etc.) is inserted during an M1/C0 integration. For example, the M1 metal interconnect is selectively etched through the ESL. Once etching is completed, tungsten (W) is filled in the C0 contact. Additionally, copper (Cu) is filled to form the M1 metal interconnect. In this example, a barrier/liner layer (e.g., tantalum nitride (TaN)/ tantalum (Ta)) is inserted between the copper (Cu) material of the M1 metal interconnect and the oxide of the ILD layer 304.

As shown in FIG. 4B, at step 410, through substrate via (TSV) openings 412, 414, are formed through the substrate 310 and the ILD layer 304, stopping on the ESL. In this example, portions of a surface of the ESL are exposed through the patterning of the TSV openings 412, 414 performed at step 410. After finishing frontside processing of the BEOL layer at step 400, at step 410, the carrier wafer 302 (see FIG. 3A) is bonded to the oxide of the top BEOL metal interconnect of the IC 300. Once bonded, the IC 300 is flipped over for backside processing. For example, the backside processing includes grinding and performing a backside chemical mechanical processing (CMP) to thin down the substrate 310. Thinning down of the substrate 310 is followed by TSV patterning and etching to form the TSV openings 412, 414, in which the ESL prevents TSV over-etch.

As shown in FIG. 4C, at step 420, sputtering is performed to remove the barrier/liner layer (e.g., TaN) of the M1 metal interconnects and the ESL at a bottom of the TSV openings 412, 414.

As shown in FIG. 4D, at step 430, an oxide liner deposition is performed in the TSV openings 412, 414, and on exposed walls of the ILD layer 304 and the substrate 310. Once the oxide liner deposition is performed, barrier liner deposition (e.g., TaN/Ta) is performed on the oxide. Next, copper (Cu) plating is performed in the TSV openings 412, 414. Finally, the backside of the IC 300 is planarized using, for example, a CMP process to complete formation of the BTSVs.

As shown in FIGS. 4A-4D, the BTSV lands on a metal (e.g., M1 metal interconnect) and dielectric (e.g., ILD layer 304) without etching through. In this implementation, a TSV bottom, and metal top are co-planar by partially landing on the dielectric layer (e.g., ILD layer 304) rather than a semiconductor layer (e.g., a silicon (Si) layer, such as the substrate 310). Various aspects of the present disclosure utilize an integration process of inserting the ESL (e.g., a dielectric etch stop layer) coplanar to metal top (e.g., M1 metal interconnect) to prevent BTSV over etch. In this implementation, a critical dimension (CD) of a BTSV bottom is greater than a metal top width. The integration process enables wafer to wafer (WoW) bonding, in which the BTSVs lands on a BEOL interconnect (e.g., the M1 metal interconnect and the ILD layer 304), in which a WoW TSV (e.g., a micro-TSV (μTSV)) may be used to implement the BTSVs.

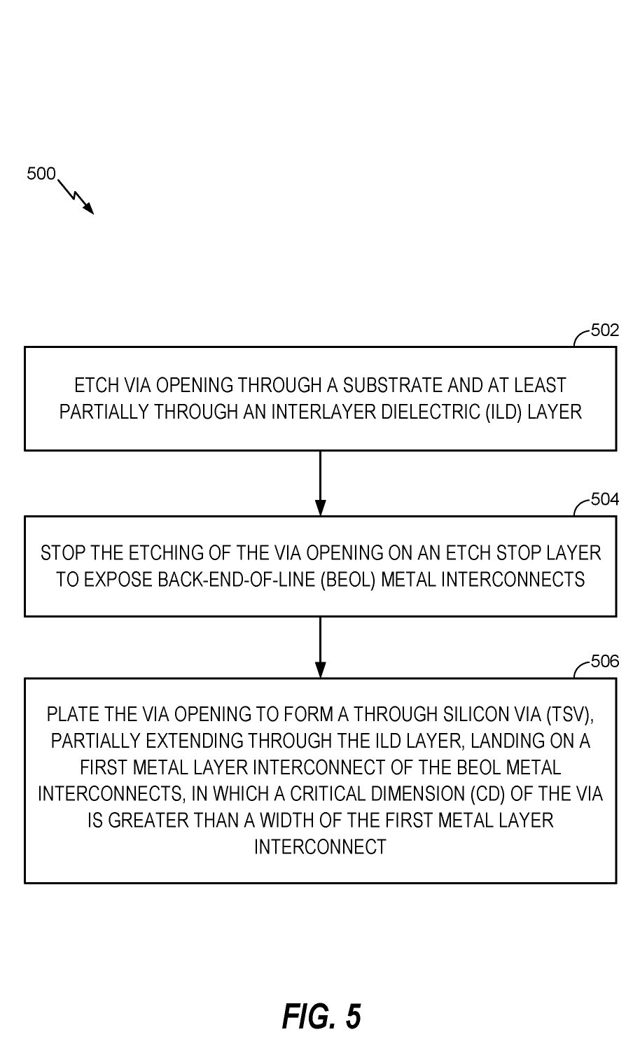

FIG. 5 is a process flow diagram illustrating a method 500 for forming a through silicon via (TSV) landing on a narrow metal, according to various aspects of the present disclosure. The method 500 begins at block 502, in which a via opening is etched through a substrate and at least partially through an interlayer dielectric (ILD) layer. For example, as shown in FIG. 4B, at step 410, through substrate via (TSV) openings 412, 414, are formed through the substrate 310 and the ILD layer 304, stopping on the ESL. In this example, portions of a surface of the ESL are exposed through the patterning of the TSV openings 412, 414 performed at step 410.

At block 504, the etching of the via opening is stop on an etch stop layer to expose back-end-of-line (BEOL) metal interconnects. For example, as shown in FIG. 3A, the ESL may be utilized to prevent BTSV etch punch-through. For example, ILD to etch stop layer etch ratio (e.g., >5) results in a predetermined etch selectivity and enables the TSV etch to stopping on ESL. In this example, the ESL is composed of silicon carbon-nitride (SiCN) and the ILD layer is composed of silicon carbon oxygen hydrogen (SiCOH).

At block 506, the via opening is plated to form a through silicon via (TSV), partially extending through the ILD layer, landing on a first metal layer interconnect of the BEOL metal interconnects, in which a critical dimension (CD) of the via is greater than a width of the first metal layer interconnect. For example, as shown in FIG. 4D, at step 430, an oxide liner deposition is performed in the TSV openings 412, 414, and on exposed walls of the ILD layer 304 and the substrate 310. Once the oxide liner deposition is performed, barrier liner deposition (e.g., TaN/Ta) is performed on the oxide. Next, copper (Cu) plating is performed in the TSV openings 412, 414. Finally, the backside of the IC 300 is planarized using, for example, a CMP process to complete formation of the BTSVs.

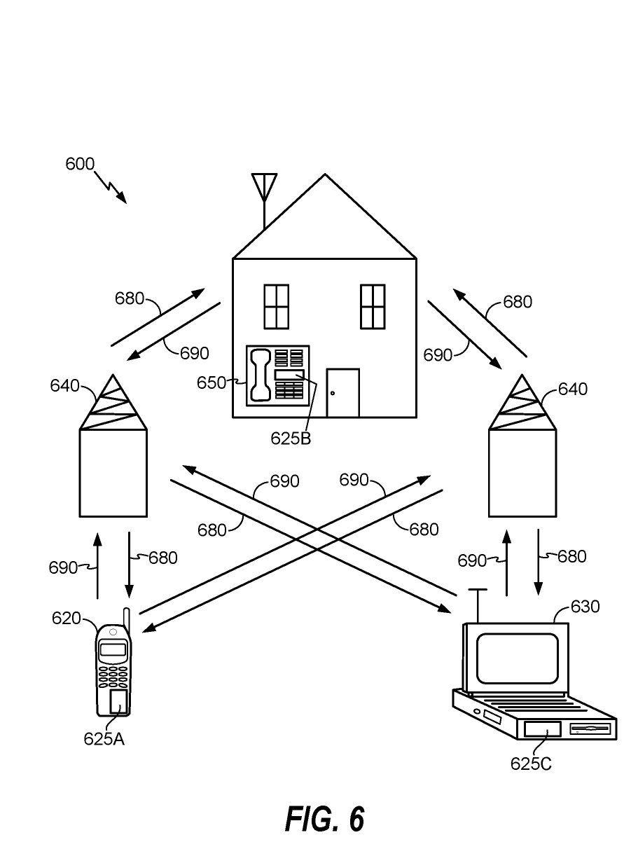

FIG. 6 is a block diagram showing an exemplary wireless communications system 600 in which an aspect of the disclosure may be advantageously employed. For purposes of illustration, FIG. 6 shows three remote units 620, 630, and 650, and two base stations 640. It will be recognized that wireless communications systems may have many more remote units and base stations. Remote units 620, 630, and 650 include integrated circuit (IC) devices 625A, 625C, and 625B that include the disclosed TSV landing on a narrow metal. It will be recognized that other devices may also include the disclosed TSV landing on a narrow metal, such as the base stations 640, switching devices, and network equipment. FIG. 6 shows forward link signals 680 from the base stations 640 to the remote units 620, 630, and 650, and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 6 illustrates remote units, according to aspects of the present disclosure, the disclosure is not limited to these exemplary illustrated units. Aspects of the present disclosure may be suitably employed in many devices, which include the disclosed TSV landing on a narrow metal.

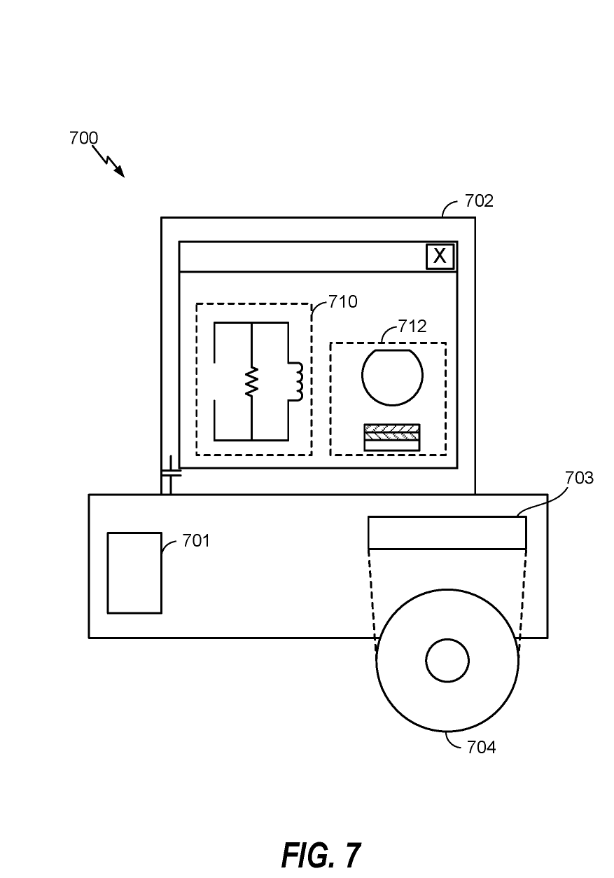

FIG. 7 is a block diagram illustrating a design workstation used for circuit, layout, and logic design of a semiconductor component, such as the through silicon via (TSV) landing on a narrow metal, as disclosed above. A design workstation 700 includes a hard disk 701 containing operating system software, support files, and design software such as Cadence or OrCAD. The design workstation 700 also includes a display 702 to facilitate design of a circuit 710 or an integrated circuit (IC) component 712 such as an TSV landing on a narrow metal. A storage medium 704 is provided for tangibly storing the design of the circuit 710 or the IC component 712 (e.g., the TSV landing on a narrow metal). The design of the circuit 710 or the IC component 712 may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit 710 or the IC component 712 by decreasing the number of processes for designing semiconductor wafers.

Implementation examples are described in the following numbered clauses:

1. An integrated circuit (IC), comprising:

a substrate;

an interlayer dielectric (ILD) layer adjacent to the substrate;

a front-end-of-line (FEOL) layer between the substrate and the ILD layer;

back-end-of-line (BEOL) metal interconnects in the ILD layer; and

a through silicon via (TSV), partially extending through the ILD layer, landing on a first metal layer interconnect of the BEOL metal interconnects, in which a critical dimension (CD) of the TSV is greater than a width of the first metal layer interconnect.

2. The IC of clause 1, in which the first metal layer interconnect comprises an M1 metal layer interconnect or a plurality of M1 metal layer interconnects contacted to the TSV.

3. The IC of any of clauses 1 or 2, in which the TSV extending from a backside of the substrate, through the substrate, to the first metal layer interconnect and the ILD layer.

4. The IC of any of clauses 1-3, in which the FEOL layer comprises a local contact (C0) coupled to an M1 metal layer interconnect of the BEOL metal interconnects.

5. The IC of any of clauses 1-4, further comprising an etch stop layer on a backside of at least some of a plurality of the first metal layer interconnects of the BEOL metal interconnects.

6. The IC of clause 5, in which the TSV to land on both an M1 metal layer interconnect of the BEOL metal interconnects and the ILD layer.

7. The IC of clause 5, in which the TSV extending from a backside of the substrate, through the substrate, the FEOL layer, to an M1 metal layer interconnect and the ILD layer.

8. The IC of clause 5, in which the TSV is in direct contact with the plurality of first metal layer interconnects and the ILD layer.

9. The IC of clause 5, in which the etch stop layer comprises silicon carbon-nitride (SiCN) and the ILD layer comprises silicon carbon oxygen hydrogen (SiCOH).

10. The IC of clause 1, in which the CD of the TSV is equal to the width of the first metal layer interconnect.

11. A method for forming a via landing on a narrow metal, comprising:

etching a via opening through a substrate and at least partially through an interlayer dielectric (ILD) layer;

stopping the etching of the via opening on an etch stop layer to expose back-end-of-line (BEOL) metal interconnects; and

plating the via opening to form a through silicon via (TSV), partially extending through the ILD layer, landing on a first metal layer interconnect of the BEOL metal interconnects, in which a critical dimension (CD) of the via is greater than a width of the first metal layer interconnect.

12. The method of clause 11, in which stopping the etching comprises selecting an etch ratio of the ILD layer to the etch stop layer to provide a predetermined etch selectivity to stop on the etch stop layer.

13. The method of any of clauses 11 or 12, in which the first metal layer interconnect comprises an M1 metal layer interconnect or a plurality of M1 metal layer interconnects contacted to the TSV.

14. The method of any of clauses 11-13, in which the TSV extending from a backside of the substrate, through the substrate, to the first metal layer interconnect and the ILD layer.

15. The method of any of clauses 11-14, in which a front-end-of-line (FEOL) layer between the substrate and the ILD layer comprises a local contact (C0) coupled to an M1 metal layer interconnect of the BEOL metal interconnects.

16. The method of any of clauses 11-15, further comprising forming the etch stop layer on a backside of at least some of a plurality of the first metal layer interconnects of the BEOL metal interconnects.

17. The method of clause 16, in which the TSV to land on both an M1 metal layer interconnect of the BEOL metal interconnects and the ILD layer.

18. The method of clause 16, in which the TSV extending from a backside of the substrate, through the substrate, to an M1 metal layer interconnect and the ILD layer.

19. The method of clause 16, in which the TSV is in direct contact with the plurality of first metal layer interconnects and the etch stop layer.

20. The method of clause 16, in which the etch stop layer comprises silicon carbon-nitride (SiCN) and the ILD layer comprises silicon carbon oxygen hydrogen (SiCOH).

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk, and Blu-ray^{®} disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC), comprising:
a substrate;
an interlayer dielectric (ILD) layer adjacent to the substrate;
a front-end-of-line (FEOL) layer between the substrate and the ILD layer;
back-end-of-line (BEOL) metal interconnects in the ILD layer; and
a through silicon via (TSV), partially extending through the ILD layer, landing on a first metal layer interconnect of the BEOL metal interconnects, in which a critical dimension (CD) of the TSV is greater than a width of the first metal layer interconnect.

2. The IC of claim 1, in which the first metal layer interconnect comprises an M1 metal layer interconnect or a plurality of M1 metal layer interconnects contacted to the TSV.

3. The IC of claim 1, in which the TSV extending from a backside of the substrate, through the substrate, to the first metal layer interconnect and the ILD layer.

4. The IC of claim 1, in which the FEOL layer comprises a local contact (C0) coupled to an M1 metal layer interconnect of the BEOL metal interconnects.

5. The IC of claim 1, further comprising an etch stop layer on a backside of at least some of a plurality of the first metal layer interconnects of the BEOL metal interconnects.

6. The IC of claim 5, in which the TSV to land on both an M1 metal layer interconnect of the BEOL metal interconnects and the ILD layer.

7. The IC of claim 5, in which the TSV extending from a backside of the substrate, through the substrate, the FEOL layer, to an M1 metal layer interconnect and the ILD layer.

8. The IC of claim 5, in which the TSV is in direct contact with the plurality of first metal layer interconnects and the ILD layer.

9. The IC of claim 5, in which the etch stop layer comprises silicon carbon-nitride (SiCN) and the ILD layer comprises silicon carbon oxygen hydrogen (SiCOH).

10. The IC of claim 1, in which the CD of the TSV is equal to the width of the first metal layer interconnect.

11. A method for forming a via landing on a narrow metal, comprising:
etching a via opening through a substrate and at least partially through an interlayer dielectric (ILD) layer;
stopping the etching of the via opening on an etch stop layer to expose back-end-of-line (BEOL) metal interconnects; and
plating the via opening to form a through silicon via (TSV), partially extending through the ILD layer, landing on a first metal layer interconnect of the BEOL metal interconnects, in which a critical dimension (CD) of the via is greater than a width of the first metal layer interconnect.

12. The method of claim 11, in which stopping the etching comprises selecting an etch ratio of the ILD layer to the etch stop layer to provide a predetermined etch selectivity to stop on the etch stop layer.

13. The method of claim 11, in which the first metal layer interconnect comprises an M1 metal layer interconnect or a plurality of M1 metal layer interconnects contacted to the TSV.

14. The method of claim 11, in which the TSV extending from a backside of the substrate, through the substrate, to the first metal layer interconnect and the ILD layer.

15. The method of claim 11, in which a front-end-of-line (FEOL) layer between the substrate and the ILD layer comprises a local contact (C0) coupled to an M1 metal layer interconnect of the BEOL metal interconnects.

16. The method of claim 11, further comprising forming the etch stop layer on a backside of at least some of a plurality of the first metal layer interconnects of the BEOL metal interconnects.

17. The method of claim 16, in which the TSV to land on both an M1 metal layer interconnect of the BEOL metal interconnects and the etch stop layer.

18. The method of claim 16, in which the TSV extending from a backside of the substrate, through the substrate, to an M1 metal layer interconnect and the etch stop layer.

19. The method of claim 16, in which the TSV is in direct contact with the plurality of first metal layer interconnects and the etch stop layer.

20. The method of claim 16, in which the etch stop layer comprises silicon carbon-nitride (SiCN) and the ILD layer comprises silicon carbon oxygen hydrogen (SiCOH).
